(19) United States
(12) Patent Application Publication
(10) Pub. No.: US 2025/0385680 A1
(43) Pub. Date: Dec. 18, 2025

(54) RECEIVER PERFORMING CLOCK AND DATA RECOVERY AND ADAPTIVE EQUALIZATION USING INTEGRATOR, AND METHOD OF OPERATING THE SAME

(71) Applicant: UIF (University Industry Foundation), Yonsei University, Seoul (KR)

(72) Inventors: Kwanseo PARK, Seoul (KR); Suil KANG, Seoul (KR)

(21) Appl. No.: 19/239,643

(22) Filed: Jun. 16, 2025

(30) Foreign Application Priority Data
Jun. 18, 2024 (KR) 10-2024-0078966

(51) Int. Cl. H03L 7/085; G06F 1/06

(52) U.S. Cl. CPC H03L 7/085; G06F 1/06

(57) ABSTRACT

The present disclosure provides a receiver capable of low power consumption and miniaturization and a method of operating the same. The receiver is capable of adaptively compensating the phase of a clock signal and ISI without using a reference voltage based on a pattern of data detected using an integrator, and a method of operating the same. The disclosed method is being performed in a receiver including a clock signal generation circuit, a 2UI integrator, a Decision Feedback Equalization (DFE), a sampling circuit, and an adaptive feedback circuit.

### CROSS-REFERENCE TO RELATED APPLICATIONS

This application claims priority under 35 U.S.C. § 119(a) to Korean Patent Application No. 10-2024-0078966, filed on Jun. 18, 2024, with the Korean Intellectual Property Office, the disclosure of which is incorporated herein in its entirety by reference.

### BACKGROUND

### 1. Technical Field

The present disclosure relates to a receiver and a method of operating the same, and more particularly, to a receiver and a method of operating the same that performs clock and data recovery and adaptive equalization using an integrator without using a separate reference voltage.

### 2. Description of the Related Art

As the amount of data used in various applications increases significantly, high-speed serial links are being used in various systems to effectively transmit large amounts of data.

FIG. 1 shows a schematic structure of a high-speed serial link system, and FIG. 2 is a drawing for explaining the alignment between data and clock signals.

Referring to FIG. 1, the high-speed serial link system includes a transmitter 10 and a receiver 20, and the transmitter 10 transmits a clock signal together with data to the receiver 20 through a data channel and a clock channel.

When a reference clock signal (Ref Clk) is applied, the transmitter 10 stabilizes the phase of the applied reference clock signal (Ref Clk) using a PLL (Phase Lock Loop) 11, and distributes the reference clock signal (Ref Clk) into a plurality of clock signals using a clock distribution circuit 12. The distributed plurality of clock signals are applied to a serializer 13 and a driver 14, while one clock signal (e.g., the reference clock signal (Ref Clk)) is transmitted to a receiver 20 through a clock channel. Then, the serializer 13 converts N bits of data applied in parallel into serial data based on the distributed plurality of clock signals (clock) from the clock distribution circuit 12, and the driver 14 also transmits the serialized data according to the distributed plurality of clock signals (clock) to the receiver 20 through a data channel. Referring to (a) of FIG. 2, the transmitter 10 may transmit a transmitter clock signal (TX Clk) and data (D₀ to D₃) synchronized to the rising edge (or falling edge) of the transmitter clock signal (TX Clk).

The transmitter clock signal (TX Clk) and data (D₀ to D₃) are delayed and distorted through the channel and transmitted to the receiver 20.

The receiver 20 receives a delayed receiver clock signal (RX Clk) and determines the transmitted data (D₀ to D₃) based on the receiver clock signal (RX Clk). The receiver 20 first removes the skew generated in the receiver clock signal (RX Clk) during transmission through the clock channel by using a deskew circuit 21, and applies the receiver clock signal (RX Clk) from which the skew has been removed to a sampler 26 and a divider 22. In this case, the deskew circuit 21 may adjust and output the phase of the receiver clock signal (RX Clk) according to the phase difference between the received data detected by a phase detection circuit 23 and the clock signal. The deskew circuit 21 may enable the sampler 26 to accurately sample data by adjusting the phase of the receiver clock signal (RX Clk) so that the rising edge (or falling edge) of the receiver clock signal (RX Clk) is positioned at the center of the section of each data (D₀ to D₃), as in (a) of FIG. 2, for example.

Meanwhile, the divider 22 divides the clock signal applied from the deskew circuit 21 into frequencies and applies the same to the deserializer 27. A continuous-time linear equalizer (hereinafter referred to as CTLE) 24 and a decision feedback equalizer (hereinafter referred to as DFE) 25 receive data transmitted from the transmitter 10 through the data channel, equalize the data, and compensate for distortion occurring during the transmission process. The sampler 26 receives data whose distortion has been compensated for by the CTLE 24 and DFE 25, and samples the applied data based on the clock signal applied from the deskew circuit 21 to determine the transmitted data (D₀ to D₃). Even though the transmitter 10 outputs data with clearly distinguished levels as shown in (a), the data is distorted by various factors including intersymbol interference (hereinafter referred to as ISI) while passing through the channel and is received by the receiver 20 in a form as shown in (b). Accordingly, the CTLE 24 and DFE 25 compensate for the distortion that occurs while the data (D₀ to D₃) passes through the channel, thereby enabling the sampler 26 to accurately determine the received data thereafter.

Then, the deserializer (27) receives data determined by the sampler 26 from the divider 22, converts the data into parallel data according to the divided clock signal, and outputs it. The phase detection circuit 23 detects the phase difference between the clock signal and the data transmitted from the transmitter 10 based on the parallel data output from the deserializer 27, generates a phase control signal based on the detected phase difference, and applies it to the deskew circuit 21.

However, in FIG. 2, (a) illustrates a case where the transmitter clock signal (TX Clk) and data (D₀ to D₃) are ideally transmitted and transmitted to the receiver 20. In reality, data (D₀ to D₃) are distorted and received due to various noises including ISI during the transmission process. Therefore, as in (b) of FIG. 2, it is difficult to distinguish the sections of each data (D₀ to D₃), and it is not easy to align the centers of the receiver clock signal (RX Clk) and data (D₀ to D₃). This reduces the sampling margin for accurately determining the data (D₀ to D₃). Therefore, the receiver 20 of a system using a high-speed serial link includes a clock and data recovery (hereinafter, CDR) circuit that compensates for and aligns the phase difference between the data and the clock signal, such as a deskew circuit 21, a phase detection circuit 23, and a sampler 26, to secure a sampling margin.

In order for the receiver 20 to effectively determine data (D₀ to D₃), the rising edge (or falling edge) of the receiver clock signal (RX Clk) must be phase-fixed while being aligned to the center of each section of the transmitted data (D₀ to D₃). Initially, the CDR circuit used a 2× oversampling technique that generates a clock signal having twice the frequency of the data and detects both the edge and each data that is applied serially, thereby aligning the clock signal and the data. However, the 2× oversampling technique has a problem in that it requires not only an increase in the clock frequency but also a large number of samplers in order to detect both the edge and the center of the data section. To solve this problem of the 2× oversampling technique, a baud-rate CDR circuit has been proposed. In the baud-rate CDR circuit, the clock signal and the data are aligned by adjusting the phase of the clock signal so that the edge of the clock signal is located at the center of the data section without detecting the edge of the data. That is, the number of required samplers can be reduced by using a clock signal of the same frequency as the data.

Meanwhile, data distortion due to various noise factors such as ISI increases with the length of the channel. In other words, loss increases with the length of the channel. Early equalizer circuits performed equalization with a fixed size considering the channel length. However, it is very difficult to accurately analyze the loss according to the channel length, and this causes problems such as over-equalization consuming unnecessary power or under-equalization, which deteriorates the performance of the entire system. To solve this problem, adaptive equalizers such as DFE 25 are currently included to adaptively compensate for the loss according to the channel length, thereby ensuring a low BER (Bit Error Rate).

However, the DFE 25 compensates for ISI by receiving a reference voltage (dLev) whose level adaptively varies according to previously determined data. In this case, the receiver 20 must be equipped with a digital-to-analog converter (hereinafter, DAC) to generate the reference voltage (dLev) applied to the DFE 25. Although the baud rate CDR circuit consumes less area and power than the 2× oversampling CDR, the DAC equipped for the DFE 25 consumes a large amount of power (for example, 35% of the receiver's power consumption) and requires a large area, which makes it difficult to miniaturize and reduce power consumption of the receiver.

### SUMMARY OF THE INVENTION

An object of the present disclosure is to provide a receiver capable of low power consumption and miniaturization and a method of operating the same.

Another object of the present disclosure is to provide a receiver capable of adaptively compensating the phase of a clock signal and ISI without using a reference voltage based on a pattern of data detected using an integrator, and a method of operating the same.

According to one embodiment of the present disclosure, a receiver includes: a clock signal generation circuit which generates a plurality of clock signals from a receiver clock signal received together with a plurality of data signals that are serially received in series; a two-unit interval (2UI) integrator which integrates the data signals that are serially received for a two-unit interval (2UI) of the data signals according to the plurality of clock signals and outputs an integrated signal; a sampling circuit which obtains data by sampling the integrated signal integrated for an one-unit interval (1UI) and generates 2UI integrated data by sampling the integrated signal integrated for 2UI; and an adaptive feedback circuit which analyzes a pattern of two or more data obtained in series and the 2UI integrated data and generates a phase control signal for adjusting a phase of the plurality of clock signals generated by the clock signal generation circuit.

The adaptive feedback circuit may, when the bit values of two consecutive data are different from each other, check a pattern according to the bit values of the two data and the 2UI integrated data, and determine a phase difference between the plurality of data signals and the plurality of clock signals according to the checked pattern to generate the phase control signal.

The adaptive feedback circuit may determine that the phase of the clock signal is ahead of the phase of the plurality of data signals when the bit values of the two data are different from each other and the bit value of the 2UI integrated data is the same as the bit value of the first data of the two data, and determine that the phase of the clock signal is behind the phase of the plurality of data signals when the bit values of the two data are different from each other and the bit value of the 2UI integrated data is different from the bit value of the first data of the two data, to generate the phase control signal.

The receiver may further include a DFE (Decision Feedback Equalization) that equalizes the integrated signal output from the 2UI integrator according to a DFE weight applied from the adaptive feedback circuit and transmits the equalized signal to the sampling circuit.

The adaptive feedback circuit may, when the bit values of two consecutive data are different from each other, check a pattern according to the bit values of the two data, the previous data, and the 2UI integrated data, and determine the equalization state of the DFE according to the checked pattern to generate the DFE weight.

The adaptive feedback circuit may determine that the equalization state of the DFE is an under-equalization state when the bit values of the two data are different from each other and the bit values of the previous data and the bit values of the 2UI integrated data are the same, and determine that the equalization state of the DFE is an over-equalization state when the bit values of the two data are different from each other and the bit values of the previous data and the bit values of the 2UI integrated data are also different from each other, to generate the DFE weight.

The clock signal generation circuit may generate the plurality of clock signals having a 2UI cycle and a 90 degree phase difference from each other, and whose phases are adjusted according to the phase control signal.

The 2UI integrator may receive two clock signals having a 2UI cycle and a 90 degree phase difference from each other, initialize a voltage level of a previously obtained integrated signal during a reset section in which both of the two clock signals are at a first level, integrate the data signal during an integration section in which a first clock signal having a phase leading from among the two clock signals is at a second level, and generate the integrated signal, and maintain the voltage level of the integrated signal during a hold section in which the first clock signal is at a first level and the level of the remaining second clock signal is at a second level.

The 2UI integrator may include first and second detection circuits which are connected in parallel between a power supply voltage and a common node, and which apply the power supply voltage to the output node pair in the reset section in response to the two clock signals, connect the output node pair and the common node in accordance with the data signal in the integration section, and block the connection between the output node pair and the common node in accordance with the first clock signal in the hold section, a bias circuit which is connected between the common node and a ground voltage and activates the first and second detection circuits by connecting the common node and the ground voltage in accordance with an applied bias voltage, and an integration circuit which integrates a signal applied through the output node pair and outputs the integrated signal.

Each of the first and second detection circuits may include two PMOS transistors connected in series between the power supply voltage and each of the two output nodes of the output node pair and receiving the first and second clock signals, respectively, and two NMOS transistors connected in series between each of the two output nodes of the output node pair and the common node and receiving one of the first clock signal and a data signal applied as a differential signal, respectively.

According to another embodiment of the present disclosure, a method of operating a receiver is provided, the method being performed in a receiver including a clock signal generation circuit, a 2UI integrator, a Decision Feedback Equalization (DFE), a sampling circuit, and an adaptive feedback circuit,

the method comprising: a step in which the clock signal generation circuit generates a plurality of clock signals from a received receiver clock signal together with a plurality of data signals that are serially received in series; a step in which the 2UI integrator integrates the data signals that are serially received for a two-unit interval (2UI) of the data signals according to the plurality of clock signals and outputs an integrated signal; a step in which the sampling circuit samples the integrated signal integrated for 1UI to obtain data and samples the integrated signal integrated for 2UI to generate 2UI integrated data; and a step in which the adaptive feedback circuit analyzes a pattern of two or more data that are serially obtained and the 2UI integrated data to generate a phase control signal for adjusting a phase of the plurality of clock signals generated by the clock signal generation circuit.

The receiver of the present disclosure and its operating method adaptively compensate for the phase of a clock signal and ISI based on a pattern of data detected using an integrator without using a reference voltage, thereby enabling low power consumption and miniaturization.

### BRIEF DESCRIPTION OF THE DRAWINGS

FIG. 1 shows a schematic structure of a high-speed serial link system.

FIG. 2 is a drawing for explaining the alignment between data and clock signals.

FIG. 3 shows a schematic structure of a receiver according to one embodiment.

FIG. 4 is a diagram for explaining the operation of the 2UI integrator of FIG. 3.

FIG. 5 shows an example of a detailed configuration of the 2UI integrator of FIG. 3.

FIG. 6 and FIG. 7 are diagrams for explaining the CDR operation of the receiver of FIG. 3.

FIG. 8 and FIG. 9 are diagrams for explaining the adaptive equalization operation of the receiver of FIG. 3.

FIG. 10 shows a clock and data recovery and an adaptive equalization method of a receiver according to one embodiment.

FIG. 11 is a diagram for explaining a computing environment including a computing device according to one embodiment.

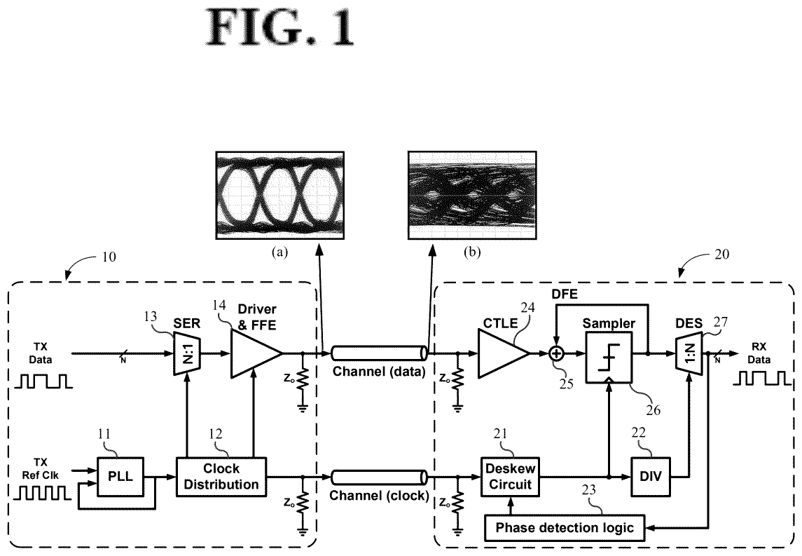

### DETAILED DESCRIPTION OF THE INVENTION

Hereinafter, specific embodiments according to the embodiments of the present disclosure will be described with reference to the drawings. The following detailed description is provided to assist in a comprehensive understanding of the methods, devices and/or systems described herein. However, this is only an example and the present invention is not limited thereto.

In describing the embodiments of the present disclosure, when it is determined that detailed descriptions of known technology related to the present disclosure may unnecessarily obscure the gist of the embodiments, the detailed descriptions thereof will be omitted. The terms used below are defined in consideration of functions in the present disclosure, but may be changed depending on the customary practice or the intention of a user or operator. Thus, the definitions should be determined based on the overall content of the present specification. The terms used herein are only for describing the embodiments, and should not be construed as limitative. Unless the context clearly indicates otherwise, the singular forms are intended to include the plural forms as well. It should be understood that the terms “comprises,” “comprising,” “includes,” and “including,” when used herein, specify the presence of stated features, numerals, steps, operations, elements, or combinations thereof, but do not preclude the presence or addition of one or more other features, numerals, steps, operations, elements, or combinations thereof. In addition, terms such as “ . . . unit”, “ . . . er/or”, “module” and “block” described in the specification means a unit for processing at least one function or operation, which may be implemented by hardware or software or a combination of hardware and software.

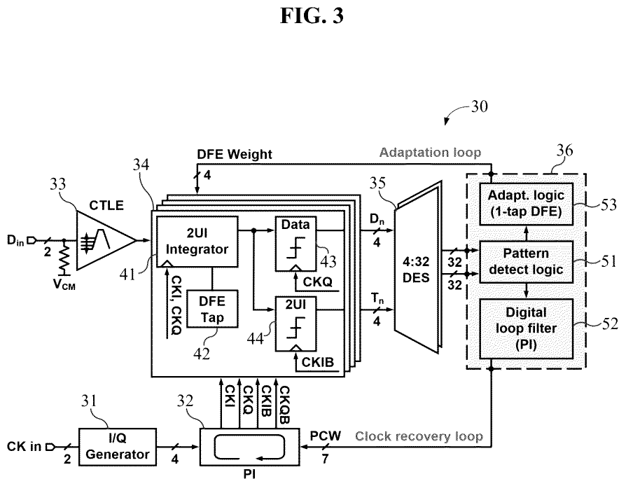

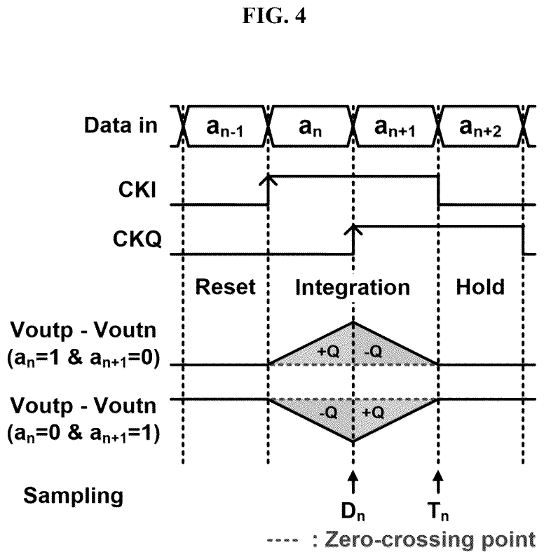

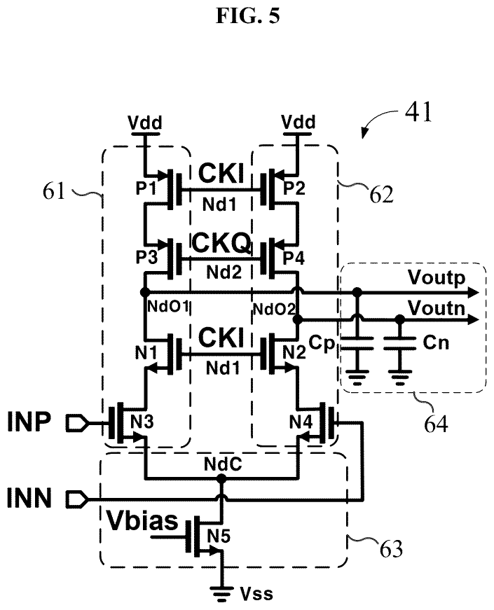

FIG. 3 shows a schematic structure of a receiver according to one embodiment, FIG. 4 is a diagram for explaining the operation of the 2UI integrator of FIG. 3, and FIG. 5 shows an example of a detailed configuration of the 2UI integrator of FIG. 3.

Referring to FIG. 3, a receiver 30 of one embodiment includes an I/Q clock generator 31, a phase interpolator (PI) 32, a continuous-time linear equalizer (hereinafter referred to as CTLE) 33, a 2UI integral sampling circuit 34, a deserializer 35, and an adaptive feedback circuit 36.

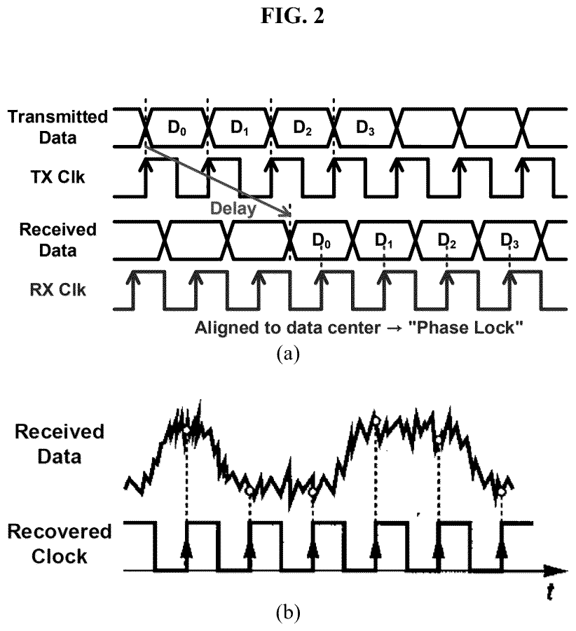

The I/Q clock generator 31 receives the receiver clock signal (CK) through the clock channel, and generates an I clock signal (CKI) and a Q clock signal (CKQ) having a phase difference of 90 degrees from the receiver clock signal (CK). Here, the receiver clock signal (CK) may be a differential signal. In addition, the I clock signal (CKI) and the Q clock signal (CKQ) may have a period corresponding to a length four times longer than a data section transmitted from the transmitter 10 through the data channel. As illustrated in (a) of FIG. 2, in a conventional high-speed serial link system, the period of the receiver clock signal (CK) was the same as the data section. However, in one embodiment, the I/Q clock generator 31 generates an I clock signal (CKI) and a Q clock signal (CKQ) having a period four times longer than conventional ones, that is, a frequency of ¼. Accordingly, the transmitter 10 may also transmit a receiver clock signal (CK) having a frequency ¼ that of the conventional one through the clock channel.

The phase interpolator 32 receives the I clock signal (CKI) and the Q clock signal (CKQ) generated from the I/Q clock generator 31, and further generates an inverted I clock signal (CKIB) and an inverted Q clock signal (CKQB) having a phase difference of 180 degrees for each of the I clock signal (CKI) and the Q clock signal (CKQ), thereby outputting an I clock signal pair (CKI, CKIB) and a Q clock signal pair (CKQ, CKQB). In this case, the phase interpolator 32 may output the I clock signal pair (CKI, CKIB) and the Q clock signal pair (CKQ, CKQB) with a phase delay in response to a phase control signal (PCW) applied from an adaptive feedback circuit 36.

Here, the I/Q clock generator 31 and the phase interpolator 32 may be said to be a clock signal generation circuit that generates a plurality of clock signals (CKI, CKIB, CKQ, CKQB) from a receiver clock signal (CK).

CTLE 33 receives data signals (aₙ₋₁, aₙ, aₙ₊₁, aₙ₊₂) that are serially transmitted at high speed through a data channel, and uses a linear peak filter to equalize the frequency response of the received data signals (aₙ₋₁, aₙ, aₙ₊₁, aₙ₊₂), thereby first reducing distortion due to channel loss.

At least one 2UI integral sampling circuit 34 receives at least two clock signals from among an I clock signal pair (CKI, CKIB) and a Q clock signal pair (CKQ, CKQB) together with data signals (aₙ₋₁, aₙ, aₙ₊₁, aₙ₊₂) that are first equalized from a CTLE 33, respectively. Then, based on the three clock signals applied, the data signals (here, aₙ, aₙ₊₁, for example) applied during a data interval (2 unit interval: 2UI) corresponding to two consecutive data among a plurality of data applied in series are integrated and equalized to obtain an integrated signal, and the applied data is determined by sampling the integrated signal integrated during 1 UI (Unit Interval) interval.

Here, it is assumed that the receiver 30 includes four 2UI integral sampling circuits 34 considering that the period of the I clock signal (CKI) and the Q clock signal (CKQ) is four times the data interval, and the configuration and operation of only one 2UI integral sampling circuit (here, the first 2UI integral sampling circuit as an example) among the four 2UI integral sampling circuits 34 are described as an example.

The 2UI integral sampling circuit 34 may include a 2UI integrator 41, a DFE 42, a data sampler 43, and a 2UI sampler 44.

The 2UI integrator 41 receives the data signals (aₙ₋₁, aₙ, aₙ₊₁, aₙ₊₂) that are first equalized in the CTLE 33, and integrates the received data signals in response to the I clock signal (CKI) and the Q clock signal (CKQ). Here, as illustrated in FIG. 4, the 2UI integrator 41 may operate by dividing it into three sections: a reset section, an integration section, and a hold section, depending on the state levels of the I clock signal (CKI) and the Q clock signal (CKQ). For example, a reset section may be defined as a period in which both the I clock signal (CKI) and the Q clock signal (CKQ) are at the first level (e.g., low level), an integration section may be defined as a period in which the I clock signal (CKI) is at the second level (e.g., high level), and a hold section may be defined as a period in which the I clock signal (CKI) is at the first level and the Q clock signal (CKQ) is at the second level.

In the reset section, the 2UI integrator 41 initializes the level of the integrated signal that has been integrated and fixed in the previous integration section and hold section. In this case, the level of the initialized integrated signal may be, for example, 0 V. Then, in the integration section, the applied data signal (aₙ, aₙ₊₁) is integrated to generate an integrated signal, and in the hold section, the level of the integrated signal generated in the integration section is maintained. In this case, since the period of the I clock signal (CKI) is four times the data section, the length of the integration section in which the I clock signal (CKI) is in the second level state is twice the data section. Therefore, the integrator generates an integrated signal by integrating the data signal applied for a period (2UI) corresponding to two data sections.

The 2UI integrator 41 may be configured based on a structure similar to a differential amplifier, as illustrated in FIG. 5, for example. Referring to FIG. 5, the 2UI integrator 41 may include first and second detection circuits 61 and 62 connected in parallel between a power supply voltage (Vdd) and a common node (NdC), a bias circuit 63 connected between the common node (NdC) and a ground voltage (Vss), and an integration circuit 64 that receives and integrates signals output from the first and second detection circuits 61 and 62.

The bias circuit 63 may include an NMOS transistor (N5) connected between a common node (NdC) and a ground voltage (Vss) and having a bias voltage (Vbias) applied to the gate. The fifth NMOS transistor (N5) of the bias circuit 63 controls whether the 2UI integrator 41 is activated by controlling the current flowing from the common node (NdC) to the ground voltage (Vss) according to the bias voltage (Vbias) applied to the gate.

The first and second detection circuits 61 and 62 are activated and operated by the bias circuit 63, and receive and amplify differential input signals (INP, INN) and output them to the integration circuit 64 through the first and second output nodes (NdO1, NdO2). Here, the differential input signals (INP, INN) may be data signals (aₙ₋₁, aₙ, aₙ₊₁, aₙ₊₂) transmitted as differential signals.

The first detection circuit 61 may include two PMOS transistors (M8, M6) and two NMOS transistors (M4, M2) connected in series between a power supply voltage (Vdd) and a common node (NdC), and the second sensing circuit 62 may include two PMOS transistors (M9, M7) and two NMOS transistors (M5, M3) connected in series between a power supply voltage (Vdd) and a common node (NdC). In the first and second detection circuits 61 and 62, the gates of the first and second PMOS transistors (P1, P2) and the first and second NMOS transistors (N1, N2) are commonly connected to a first node (Nd1) to which an I clock signal (CKI) is applied, and the gates of the third and fourth PMOS transistors (P3, P4) are commonly connected to a second node (Nd2) to which a Q clock signal (CKQ) is applied. In addition, the third and fourth NMOS transistors (N3, N4) are input transistors, and differential input signals (INP, INN) are applied to the gates of the third and fourth NMOS transistors (N3, N4), respectively. Here, since it is assumed that the 2UI integrator 41 of the first 2UI integral sampling circuit 34 among at least one 2UI integral sampling circuit 34 is used, it is explained that the I clock signal (CKI) and the Q clock signal (CKQ) are applied to the first and second nodes (Nd1, Nd2), respectively. In the case of the 2UI integrator 41 of another 2UI integral sampling circuit 34, two different clock signals among the I clock signal pair (CKI, CKIB) and the Q clock signal pair (CKQ, CKQB) may be applied.

In the first detection circuit 61, the amplified first signal is applied to the integration circuit 64 through the first output node (NdO1) between the third PMOS transistor (P3) and the first NMOS transistor (N1), and in the second detection circuit 62, the amplified second signal is applied to the integration circuit 64 through the second output node (NdO2) between the fourth PMOS transistor (P4) and the second NMOS transistor (N2).

Meanwhile, the integration circuit 64 may include a first capacitor (Cp) connected between the first output node (NdO1) between the third PMOS transistor (P3) and the first NMOS transistor (P1) and the ground voltage (Vss), and a second capacitor (Cn) connected between the second output node (NdO2) and the ground voltage (Vss).

Hereinafter, the operation of the 2UI integrator 41 will be described with reference to FIGS. 4 and 5. However, the operation of the above-mentioned 2UI integrator 41 is explained here assuming an ideal state in which the phases are adjusted so that the edges of the data signals (aₙ₋₁, aₙ, aₙ₊₁, aₙ₊₂) and the edges of the I clock signal (CKI) and the Q clock signal (CKQ) coincide, and distortion due to ISI is eliminated.

When the 2UI integrator 41 operates, first, the fifth NMOS transistor (N5) in the bias circuit 63 is turned on, and the first and second detection circuits 61 and 62 are activated by the bias voltage (Vbias). Then, in the reset section where both the I clock signal (CKI) and the Q clock signal (CKQ) are at the first level (low level here), the first to fourth PMOS transistors (P1 to P4) are all turned on, while the first and second NMOS transistors (N1, N2) are turned off, so that the first and second output nodes (NdO1, NdO2) are both pulled up to the power supply voltage level. Therefore, both the first and second capacitors (Cp, Cn) connected to the first and second output nodes (NdO1, NdO2) are charged to the power supply voltage level, and thus the output signal pair (Voutp, Voutn) is reset to the same power supply voltage (Vdd) level.

Thereafter, in the integration section where the I clock signal (CKI) rises to the second level (here, a high level), the first and second PMOS transistors (P1, P2) are turned off, while the first and second NMOS transistors (N1, N2) are turned on. The third and fourth transistors (P3, P4) may be maintained in a turn-on state and then turned off, according to the Q clock signal (CKQ). However, since the first and second PMOS transistors (P1, P2) are already turned off, the operation in the integration section of the 2UI integrator 41 is not affected.

In the first UI integration section where the Q clock signal (CKQ) is maintained at the first level in the integration section, the differential data signal (aₙ) is applied as a differential input signal (INP, INN) to the third and fourth NMOS transistors (N3, N4). In this case, the differential input signals (INP, INN) may be applied as signals (INP=Vcm+Vswing, INN=Vcm−Vswing) having a difference by a swing voltage (Vswing) with respect to the common mode voltage (Vcm). Accordingly, the third and fourth NMOS transistors (N3, N4) are both turned on by the common mode voltage (Vcm) of the differential input signals (INP, INN), but the first and second output nodes (NdO1, NdO2) are discharged to different voltage levels, so that the voltage levels of the output signal pair (Voutp, Voutn) are adjusted differently from each other. Here, the first output node (NdO1) may be discharged to the Vdd−(Vcm+Vswing) level, and the second output node (NdO2) may be discharged to the Vdd−(Vcm−Vswing) level. That is, the output signal pair (Voutp, Voutn) has a voltage level according to the data signal (aₙ).

Then, in the second UI integration section where the Q clock signal (CKQ) rises to the second level, the differential data signal (aₙ₊₁) is applied as a differential input signal (INP, INN) to the third and fourth NMOS transistors (N3, N4), so that the output signal pair (Voutp, Voutn) has a voltage level according to the data signal (aₙ₊₁).

Here, when the two data signals (aₙ, aₙ₊₁) applied in the integration section are signals for the same bit value, −2Vswing is integrated as a voltage difference (Voutp−Voutn) across the first and second capacitors (Cp, Cn) in the first UI integration section, and −2Vswing is integrated again in the second UI integration section, so a voltage difference of −4Vswing is integrated in the entire integration section. Accordingly, the output signal pair (Voutp, Voutn) is output with a voltage difference of −4Vswing.

However, when the two data signals (aₙ, aₙ₊₁) applied in the integration section are signals for different bit values, −2Vswing is integrated as a voltage difference (Voutp−Voutn) across the first and second capacitors (Cp, Cn) in the first UI integration section, but +2Vswing is integrated in the second UI integration section and they cancel each other out, so the integrated voltage difference in the entire integration section becomes 0V.

Therefore, as shown in the lower part of FIG. 4, when the two data signals (aₙ, aₙ₊₁) applied in the integration section are signals for different bit values, the voltage difference (Voutp−Voutn) between the first output signal (Voutp) and the second output signal (Voutn) should be −2Vswing in the first UI integration section, and the voltage difference should disappear in the second UI integration section.

Thereafter, in the hold section where the I clock signal (CKI) transitions downward to the first level and the Q clock signal (CKQ) is maintained at the second level, the first and second output nodes (NdO1, NdO2) are made floating by the third and fourth PMOS transistors (P3, P4) which are maintained in the turned-off state and the first and second NMOS transistors (N1, N2) which are turned off, and the output signal pair (Voutp, Voutn) maintains the voltage level charged to the first and second capacitors (Cp, Cn).

The DFE 42 performs equalization by adjusting the level of the integrated signal output from the 2UI integrator 41 according to the DFE weight fed back from the adaptive feedback circuit 36. The DFE 42 may adaptively compensate for distortion caused by ISI that occurs differently depending on the transmitted data (Dₙ₋₁, Dₙ, Dₙ₊₁, Dₙ₊₂), by adjusting the level of the integrated signal output from the 2UI integrator 41 according to the DFE weight generated by analyzing the pattern of data (Dₙ₋₁, Dₙ, Dₙ₊₁, Dₙ₊₂) determined and applied by at least one 2UI integral sampling circuit 34 by an adaptive feedback circuit 36. Since the DFE 42 performs equalization according to the DFE weight fed back from the adaptive feedback circuit 36, a separate reference voltage (dLev) is not required in the receiver 30 of one embodiment to enable the DFE 42 to perform adaptive equalization. Accordingly, a DAC for generating the reference voltage (dLev) is not required, which can reduce power consumption and size.

Meanwhile, the data sampler 43 receives the integrated signal generated by the 2UI integrator 41 and equalized by the DFE 42, and samples the received integrated signal in response to the edge (here, a rising edge, for example) of the Q clock signal (CKQ) to determine the transmitted data (Dₙ). In this case, as illustrated in FIG. 4, the integrated signal is generated by integrating the applied data signal for a 2UI section, with the integration section starting from the rising edge of the I clock signal (CKI), but the Q clock signal (CKQ) has a phase difference of 90 degrees compared to the I clock signal (CKI). Therefore, the data (Dₙ) sampled by the data sampler 43 can be viewed as a sampling result for a single data signal (aₙ) integrated for 1 UI section when the edges of the data signals (aₙ₋₁, aₙ, aₙ₊₁, aₙ₊₂) are synchronized with the edges of the I clock signal (CKI) and the Q clock signal (CKQ). That is, one data (Dₙ) can be obtained.

As described above, since both the I clock signal (CKI) and the Q clock signal (CKQ) have a period four times that of the data interval, the data sampler 43 of the 2UI integral sampling circuit 34 may perform sampling on one of the four data that are continuously applied. Accordingly, the receiver 30 may be equipped with four 2UI integral sampling circuits 34 so that it can sample all data signals (aₙ₋₁, aₙ, aₙ₊₁, aₙ₊₂) that are continuously applied in series at high speed.

In addition, the 2UI sampler 44 receives the integrated signal integrated during the 2UI section from the 2UI integrator 41 and samples it to obtain 2UI integrated data (Tₙ). Here, the 2UI integrated data (Tₙ) has a value according to the result of the integration of data signals (aₙ, aₙ₊₁) for two data (Dₙ, Dₙ₊₁). In FIG. 3, the 2UI sampler 44 is illustrated as obtaining the 2UI integrated data (Tₙ) by sampling the integrated signal at the rising edge of the inverted I clock signal (CKIB), but the 2UI sampler 44 may also obtain the 2UI integrated data (Tₙ) by sampling the integrated signal at the falling edge of the I clock signal (CKI).

Here, the data sampler 43 and the 2UI sampler 44 may be integrated and called a sampling circuit.

The deserializer 35 converts data (Dₙ₋₁, Dₙ, Dₙ₊₁, Dₙ₊₂) and 2UI integrated data (Tₙ₋₁, Tₙ, Tₙ₊₁, Tₙ₊₂) applied from at least one 2UI integral sampling circuit 34 into parallel and transmits them to the adaptive feedback circuit 36.

The adaptive feedback circuit 36 receives data (Dₙ₋₁, Dₙ, Dₙ₊₁, Dₙ₊₂) and 2UI integrated data (Tₙ) determined by at least one 2UI integral sampling circuit 34. Then, based on the pattern of the received data (Dₙ₋₁, Dₙ, Dₙ₊₁, Dₙ₊₂) and the 2UI integrated data (Tₙ), the phase interpolator 32 generates a phase control signal (PCW) for delaying the phase of the I clock signal pair (CKI, CKIB) and the Q clock signal pair (CKQ, CKQB), while the DFE 42 generates a DFE weight for adjusting the ISI equalization level.

The adaptive feedback circuit 36 may include a pattern detection circuit 51, a phase control signal generation circuit 52, and an adaptive weight generation circuit 53.

The pattern detection circuit 51 analyzes the pattern of the data (Dₙ₋₁, Dₙ, Dₙ₊₁, Dₙ₊₂) and the 2UI integrated data (Tₙ) obtained from at least one 2UI integral sampling circuit 34. The pattern detection circuit 51 analyzes the pattern of the two data (Dₙ, Dₙ₊₁) that are applied sequentially and the 2UI integrated data (Tₙ) and obtains phase state information, to recovery and synchronize the phases of the clock signal (CKI, CKIB, CKQ, CKQB) and the data signal (aₙ₋₁, aₙ, aₙ₊₁, aₙ₊₂). In addition, the pattern detection circuit 51 analyzes the pattern of the three data (Dₙ₋₁, Dₙ, Dₙ₊₁) and the 2UI integrated data (Tₙ) and obtains equalization state information, to compensate for distortion due to ISI. Then, the obtained phase state information is applied to the phase control signal generation circuit 52, and the equalization state information is applied to the adaptive weight generation circuit 53.

However, in one embodiment, the pattern detection circuit 51 may not analyze the pattern for all of the applied data (Dₙ₋₁, Dₙ, Dₙ₊₁, Dₙ₊₂), but analyze the pattern together with the 2UI integrated data (Tₙ) when the bit values of two data (Dₙ, Dₙ₊₁) applied sequentially are different from each other, thereby obtaining the phase state information and the equalization state information. This is because the 2UI integrator 41 of at least one 2UI integral sampling circuit 34 is configured to integrate two data signals (aₙ, aₙ₊₁), and when the bit values of the data (Dₙ, Dₙ₊₁) according to the two data signals (aₙ, aₙ₊₁) are different from each other, the integrated value should be derived as 0, so that the phase difference between the clock signals (CKI, CKIB, CKQ, CKQB) and the data signals (aₙ₋₁, aₙ, aₙ₊₁, aₙ₊₂) or distortion due to ISI can be easily detected.

The detailed method by which the pattern detection circuit 51 obtains phase state information and equalization state information will be described later.

The phase control signal generation circuit 52 generates a phase control signal (PCW) according to the phase state information applied from the pattern detection circuit 51 and applies it to the phase interpolator 32, thereby controlling the phase of the I clock signal pair (CKI, CKIB) and the Q clock signal pair (CKQ, CKQB) generated by the phase interpolator 32. That is, the phase of the I clock signal pair (CKI, CKIB) and the Q clock signal pair (CKQ, CKQB) is synchronized with the edge of the data signal (aₙ₋₁, aₙ, aₙ₊₁, aₙ₊₂).

In addition, the adaptive weight generation circuit 53 generates DFE weights according to the applied equalization state information and applies them to the DFE 42 of the 2UI integral sampling circuit 34, thereby enabling the DFE 42 to adaptively compensate for distortion caused by ISI in the applied data signals (aₙ₋₁, aₙ, aₙ₊₁, aₙ₊₂). In other words, the DFE 42 can perform adaptive equalization according to the bit value of the data applied from the transmitter 10 without using the reference voltage (dLev).

In the receiver of the FIG. 3, it can be seen that the 2UI integrator 41, the data sampler 43, the 2UI sampler 44, the pattern detection circuit 51, and the phase control signal generation circuit 52 constitute the CDR circuit, and the CTLE 33, the 2UI integrator 41, the DFE 42, the data sampler 43, the 2UI sampler 44, the pattern detection circuit 51, and the adaptive weight generation circuit 53 constitute the equalizer circuit.

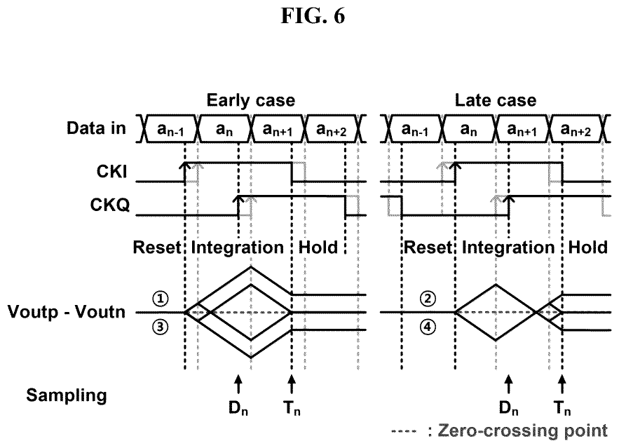

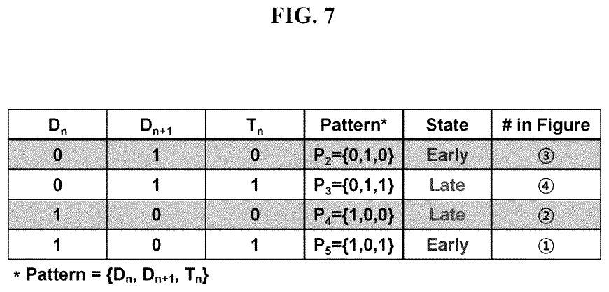

FIG. 6 and FIG. 7 are diagrams for explaining the CDR operation of the receiver.

As described above, in the present disclosure, among data signals (aₙ₋₁, aₙ, aₙ₊₁, aₙ₊₂) serially applied to the receiver 30, the data signals applied during a 2UI period, that is, a period corresponding to two data signals applied consecutively, are integrated to obtain 2UI integrated data (Tₙ). In this case, when data signals (here, for example, aₙ, aₙ₊₁) for data (here, for example, Dₙ, Dₙ₊₁) having different bit values are applied, and the data signals (here, for example, aₙ, aₙ₊₁) and clock signals (CKI, CKIB, CKQ, CKQB) are synchronized, the voltage difference (Voutp−Voutn) between the output signals (Voutp, Voutn) where the data signals (here, for example, aₙ, aₙ₊₁) are integrated and output in the 2UI integrator 41 having the structure of FIG. 5 must first increase or decrease while the data signal (aₙ) is applied, as shown in the lower part of FIG. 4, and then be recovered to 0 again while the next data signal (aₙ₊₁) is applied. Specifically, when data (Dₙ, Dₙ₊₁) for each data signal (aₙ, aₙ₊₁) has bit values of 1 and 0, the voltage difference (Voutp−Voutn) should rise for 1 UI interval and fall for the next 1 UI interval to become 0, whereas when data (Dₙ, Dₙ₊₁) has bit values of 0 and 1, the voltage difference (Voutp−Voutn) should fall for 1 UI interval and rise for the next 1 UI interval to become 0. In other words, the absolute value (|Voutp−Voutn|) of the voltage difference (Voutp−Voutn) should increase and then decrease to recover to 0.

However, when the data signal (aₙ, aₙ₊₁) and the clock signals (CKI, CKIB, CKQ, CKQB) are not synchronized, as shown in FIG. 6, after the 2UI section, the voltage difference (Voutp−Voutn) of the output signal (Voutp, Voutn) output from the 2UI integrator 41 becomes non-zero. The left side of FIG. 6 shows the case where the phase of the clock signal (CKI, CKQ) is earlier than the data signal (aₙ, aₙ₊₁) (early case), and the right side shows the case where the phase of the clock signal (CKI, CKQ) is later than the data signal (aₙ, aₙ₊₁) (early case). As shown in FIG. 6, when the phase of the clock signal (CKI, CKQ) is earlier or later than the data signal (aₙ, aₙ₊₁), the absolute value (|Voutp−Voutn|) of the voltage difference increases and then cannot be recovered to 0. Accordingly, the pattern detection circuit 51 may obtain phase state information by analyzing the phase state of the data signal (aₙ, aₙ₊₁) and the clock signals (CKI, CKIB, CKQ, CKQB) according to the pattern of the two data (Dₙ, Dₙ₊₁) obtained from the data sampler 43 and the 2UI integrated data (Tₙ) obtained from the 2UI sampler 44, as shown in the table in FIG. 7.

As described above, since the phase state cannot be analyzed when two data (Dₙ, Dₙ₊₁) have the same bit value, the pattern detection circuit 51 analyzes the phase state only when the two data (Dₙ, Dₙ₊₁) have different bit values to obtain phase state information. Accordingly, in FIG. 7, only the pattern when the two data (Dₙ, Dₙ₊₁) have different bit values is illustrated.

Referring to FIGS. 6 and 7, when the bit value of the nth data (Dₙ) is 0 and the bit value of the n+1th data (Dₙ₊₁) is 1, which are different from each other, and the 2UI integrated data (Tₙ) is 0, then this corresponds to case \textcircled{3} of FIG. 7, and the pattern detection circuit 51 determines that the phase of the clock signal (CKI, CKQ) is early. However, when the 2UI integrated data (Tₙ) is 1, this corresponds to case \textcircled{4} of FIG. 7, and the pattern detection circuit 51 determines that the phase of the clock signal (CKI, CKQ) is late, and generates phase state information.

On the other hand, when the bit value of the nth data (Dₙ) is 1 and the bit value of the n+1th data (Dₙ₊₁) is 0, which are different from each other, and the 2UI integrated data (Tₙ) is 0, then this corresponds to case \textcircled{2} of FIG. 7, and the pattern detection circuit 51 determines that the phase of the clock signal (CKI, CKQ) is late, but when the 2UI integrated data (Tₙ) is 1, then this corresponds to case \textcircled{1} of FIG. 7, and the pattern detection circuit determines that the phase of the clock signal (CKI, CKQ) is late, and generates phase state information.

That is, when the bit values of the two data (Dₙ, Dₙ₊₁) are different from each other and the bit value of the 2UI integrated data (Tₙ) is the same as the bit value of the first data (Dₙ), it may be determined that the phase of the clock signal (CKI, CKQ) is ahead of the data signal (aₙ₋₁, aₙ, aₙ₊₁, an+2), and when the bit value of the 2UI integrated data (Tₙ) is the same as the bit value of the second data (Dₙ₊₁), it may be determined that the phase of the clock signal (CKI, CKQ) is behind the data signal (aₙ₋₁, aₙ, aₙ₊₁, an+2).

Therefore, the pattern detection circuit 51 may determine the phase difference between the data signal (aₙ, aₙ₊₁) and the clock signals (CKI, CKIB, CKQ, CKQB), based on the pattern of two data (Dₙ, Dₙ₊₁) that are applied sequentially with different bit values and the 2UI integrated data (Tₙ).

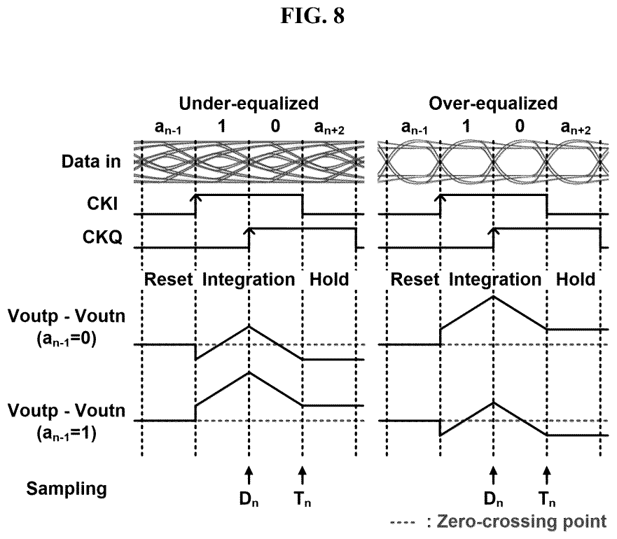

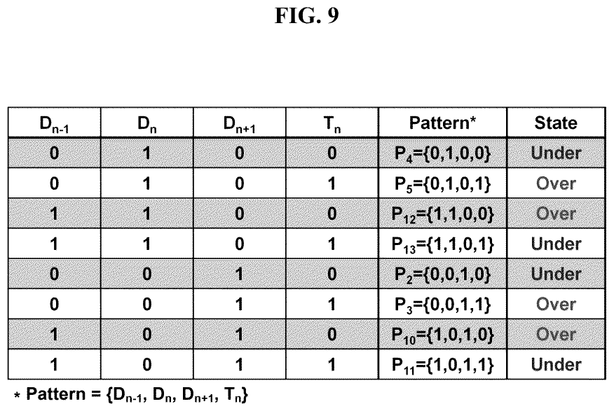

FIG. 8 and FIG. 9 are diagrams for explaining the adaptive equalization operation of the receiver of FIG. 3.

In FIG. 8, it is assumed that the data signals (aₙ, aₙ₊₁) and the clock signals (CKI, CKIB, CKQ, CKQB) are synchronized, and the left side of FIG. 8 shows the case of under-equalization, and the right side shows the case of over-equalization. In addition, since the distortion due to ISI is that the component of the previous data signal (aₙ₋₁) affects the subsequent data signal (aₙ, aₙ₋₁), in FIG. 8, the cases where the bit value of the data (Dₙ₋₁) for the previous data signal (aₙ₋₁) is 0 and 1 are distinguished at the bottom, and the bit value of the data (Dₙ, Dₙ₊₁) for the data signal (aₙ, aₙ₋₁) is assumed to be 1 and 0.

As shown on the left side of FIG. 8, in the under-equalization state, when the bit value of the previous data signal (aₙ₋₁) is 0, the voltage difference (Voutp−Voutn) of the output signals (Voutp, Voutn) becomes a negative value, so that the 2UI integrated data (Tₙ) becomes 0, and when the bit value of the previous data signal (aₙ₋₁) is 1, the voltage difference (Voutp−Voutn) of the output signals (Voutp, Voutn) becomes a positive value, so that the 2UI integrated data (Tₙ) becomes 1.

On the other hand, in the over-equalization state, as shown on the right, when the bit value of the previous data signal (aₙ₋₁) is 0, the voltage difference (Voutp−Voutn) of the output signals (Voutp, Voutn) becomes a positive value, so the 2UI integrated data (Tₙ) becomes 1, and when the bit value of the previous data signal (aₙ₋₁) is 1, the voltage difference (Voutp−Voutn) of the output signals (Voutp, Voutn) becomes a negative value, so the 2UI integrated data (Tₙ) becomes 0.

Accordingly, the pattern detection circuit 51 may obtain equalization status information by analyzing the pattern of three consecutive data (Dₙ₋₁, Dₙ, Dₙ₊₁) and 2UI integrated data (Tₙ), as shown in the table in FIG. 9. In FIG. 9, only eight patterns that can be had when two data (Dₙ, Dₙ₊₁) have different bit values are shown.

The pattern detection circuit 51 may determine that when the bit value of the nth data (Dₙ) is 0 and the bit value of the n+1th data (Dₙ₊₁) is 1, which are different from each other, and the bit value of the n−1th data (Dₙ₋₁) is 0, then when the 2UI integrated data (Tₙ) is 0, then it is an under-equalization state, and when the 2UI integrated data (Tₙ) is 1, then it is an over-equalization state. In addition, it may determine that when the bit value of the n−1th data (Dₙ₋₁) is 1, then when the 2UI integrated data (Tₙ) is 0, then it is an over-equalization state, and when the 2UI integrated data (Tₙ) is 1, then it is an under-equalization state.

In addition, even when the bit value of the nth data (Dₙ) is 1 and the bit value of the n+1th data (Dₙ₊₁) is 0, it may determine that when the bit value of the n−1th data (D_{n-1) is} 0 and the 2UI integrated data (Tₙ) is 0, it is an under-equalization state, and when the 2UI integrated data (Tₙ) is 1, it is an over-equalization state, and it may determine that when the bit value of the n−1th data (Dₙ₋₁) is 1 and the 2UI integrated data (Tₙ) is 0, it is an over-equalization state, and when the 2UI integrated data (Tₙ) is 1, it is an under-equalization state.

That is, when the bit values of the two data (Dₙ, Dₙ₊₁) are different from each other (0, 1 or 1, 0), and the bit value of the previous data (Dₙ₋₁) and the bit value of the 2UI integrated data (Tₙ) are the same (0, 0 or 1, 1), the pattern detection circuit 51 may determine that the equalization state of the DFE 42 is an under-equalization state, and when the bit values of the two data (Dₙ, Dₙ₊₁) are different from each other, and the bit value of the previous data (Dₙ₋₁) and the bit value of the 2UI integrated data (Tₙ) are also different from each other, it may determine that the equalization state of the DFE 42 is an over-equalization state.

As described above, the pattern detection circuit 51 may obtain phase state information from a pattern of two consecutive data (Dₙ, Dₙ₊₁) and 2UI integrated data (Tₙ), and may obtain equalization state information from a pattern of three consecutive data (Dₙ₋₁, Dₙ, Dₙ₊₁) and 2UI integrated data (Tₙ), so that the CDR circuit and the adaptive equalization circuit can not only efficiently synchronize the phases of the data signals (aₙ₋₁, aₙ, aₙ₊₁, aₙ₊₂) and the clock signals (CKI, CKIB, CKQ, CKQB), but also effectively compensate for distortion due to ISI of the data signals (aₙ₋₁, aₙ, aₙ₊₁, aₙ₊₂) regardless of the channel state without using the reference voltage (dLev).

The pattern detection circuit 51 may perform phase adjustment and adaptive equalization whenever the bit values of the continuously applied data (Dₙ, Dₙ₊₁, Dₙ₊₂) are different, but may also perform phase adjustment and adaptive equalization at regular intervals. However, since the results of phase adjustment and adaptive equalization affect each other, the pattern detection circuit 51 may not perform phase adjustment and adaptive equalization simultaneously, but may perform phase adjustment and adaptive equalization alternately. For example, the pattern detection circuit 51 may first perform phase adjustment for a certain period of time, and then perform adaptive equalization in the next period. In addition, the pattern detection circuit 51 may perform phase adjustment and adaptive equalization alternately and repeatedly.

In the illustrated embodiment, respective configurations may have different functions and capabilities in addition to those described above, and may include additional configurations in addition to those described above. In addition, in an embodiment, each configuration may be implemented using one or more physically separated devices, or may be implemented by one or more processors or a combination of one or more processors and software, and may not be clearly distinguished in specific operations unlike the illustrated example.

In addition, each component of the receiver shown in FIG. 3 may be implemented in a logic circuit by hardware, firm ware, software, or a combination thereof or may be implemented using a general purpose or special purpose computer. The apparatus may be implemented using hardwired device, field programmable gate array

(FPGA) or application specific integrated circuit (ASIC). Further, the apparatus may be implemented by a system on chip (SoC) including one or more processors and a controller.

In addition, the receiver may be mounted in a computing device or server provided with a hardware element as a software, a hardware, or a combination thereof. The computing device or server may refer to various devices including all or some of a communication device for communicating with various devices and wired/wireless communication networks such as a communication modem, a memory which stores data for executing programs, and a microprocessor which executes programs to perform operations and commands.

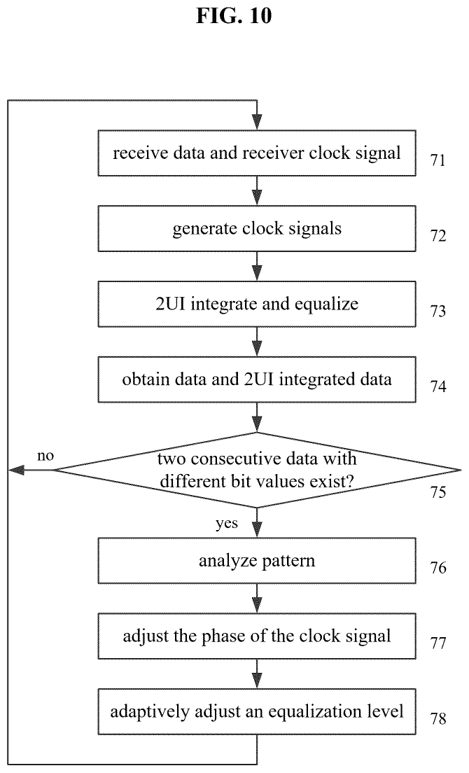

FIG. 10 shows a clock and data recovery and an adaptive equalization method of a receiver according to one embodiment.

The clock and data recovery and adaptive equalization method of the receiver of one embodiment may be performed in the receiver 30. Referring to FIG. 10, the receiver 30 first receives a plurality of data signals (aₙ₋₁, aₙ, aₙ₊₁, aₙ₊₂) continuously transmitted in high-speed serial from the transmitter 10 and a receiver clock signal (CK) (71). Then, clock signals (CKI, CKIB, CKQ, CKQB) having a phase according to previously set phase state information are generated from the receiver clock signal (CK) (72). Using the generated clock signals (CKI, CKIB, CKQ, CKQB), the data signals applied during a 2UI period, which is a time period in which two consecutive data signals are applied, are integrated, and equalized according to previously set equalization state information (73). In this case, the equalization may be performed using a DFE 42 whose equalization level is adjusted according to the DFE weights that are fed back and applied. Then, by sampling the 1UI integrated signal integrated for 1UI from the integrated signal in which data signals are integrated during the 2UI section, data (Dₙ₋₁, Dₙ, Dₙ₊₁, Dₙ₊₂) for each of the applied plurality of data signals (aₙ₋₁, aₙ, aₙ₊₁, aₙ₊₂) is obtained, and 2UI integrated data (Tₙ) is obtained by sampling the 2UI integrated signal integrated during the 2UI section (74).

Once the plurality of data (Dₙ₋₁, Dₙ, Dₙ₊₁, Dₙ₊₂) and 2UI integrated data (Tₙ) are obtained, it is determined whether there are two consecutive data (here, Dₙ, Dₙ₊₁as an example) with different bit values among the obtained plurality of data (Dₙ₋₁, Dₙ, Dₙ₊₁, Dₙ₊₂) (75). When it is determined that there are two consecutive data (Dₙ, Dₙ₊₁) with different bit values, the pattern of the two determined data (Dₙ, Dₙ₊₁) and the previous data (Dₙ₋₁) and the 2UI integrated data (Tₙ) is analyzed (76).

Then, as shown in the table of FIG. 7, based on the result of pattern analysis of two data (Dₙ, Dₙ₊₁) and 2UI integrated data (Tₙ), it is determined whether the phase of the previously generated clock signal (CKI, CKIB, CKQ, CKQB) is early or late in comparison with the data signal transmitted from the transmitter 10, thereby obtaining phase state information, and generating a phase control signal (PCW) based on the obtained phase state information to adjust the phase of the clock signal (CKI, CKIB, CKQ, CKQB) (77).

Then, as shown in the table of FIG. 7, based on the result of pattern analysis of 1 data (Dₙ₋₁, Dₙ, Dₙ₊₁) and 2UI integrated data (Tₙ), an equalization state indicating whether the already received data signal (aₙ₋₁, aₙ, aₙ₊₁, aₙ₊₂) is over-equalized or under-equalized is checked, and an equalization weight is generated based on the checked equalization state, so as to adaptively adjust an equalization level to be applied to subsequently applied data (78).

In FIG. 10, it is described that respective processes are sequentially executed, which is, however, illustrative, and those skilled in the art may apply various modifications and changes by changing the order illustrated in FIG. 10 or performing one or more processes in parallel or adding another process without departing from the essential gist of the exemplary embodiment of the present disclosure.

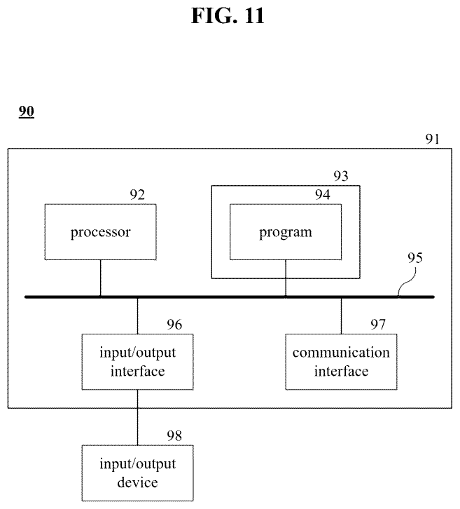

FIG. 11 is a diagram for explaining a computing environment including a computing device according to one embodiment.

In the illustrated embodiment, respective configurations may have different functions and capabilities in addition to those described below, and may include additional configurations in addition to those described below. The illustrated computing environment 90 may include a computing device 91 to perform the clock and data recovery and adaptive equalization method of a receiver illustrated in FIG. 10. In an embodiment, the computing device 91 may be one or more components included in the receiver shown in FIG. 3.

The computing device 91 includes at least one processor 92, a computer readable storage medium 93 and a communication bus 95. The processor 92 may cause the computing device 91 to operate according to the above-mentioned exemplary embodiment. For example, the processor 92 may execute one or more programs 94 stored in the computer readable storage medium 93. The one or more programs 94 may include one or more computer executable instructions, and the computer executable instructions may be configured, when executed by the processor 92, to cause the computing device 91 to perform operations in accordance with the exemplary embodiment.

The communication bus 95 interconnects various other components of the computing device 91, including the processor 92 and the computer readable storage medium 93.

The computing device 91 may also include one or more input/output interfaces 96 and one or more communication interfaces 97 that provide interfaces for one or more input/output devices 98. The input/output interfaces 96 and the communication interfaces 97 are connected to the communication bus 95. The input/output devices 98 may be connected to other components of the computing device 91 through the input/output interface 96. Exemplary input/output devices 98 may include input devices such as a pointing device (such as a mouse or trackpad), keyboard, touch input device (such as a touchpad or touchscreen), voice or sound input device, sensor devices of various types and/or photography devices, and/or output devices such as a display device, printer, speaker and/or network card. The exemplary input/output device 98 is one component constituting the computing device 91, may be included inside the computing device 91, or may be connected to the computing device 91 as a separate device distinct from the computing device 91.

The present disclosure has been described in detail through a representative embodiment, but those of ordinary skill in the art to which the art pertains will appreciate that various modifications and other equivalent embodiments are possible. Therefore, the true technical protection scope of the present invention should be determined by the technical spirit set forth in the appended scope of claims.

What is claimed is:

1. A receiver comprising:
a clock signal generation circuit which generates a plurality of clock signals from a receiver clock signal received together with a plurality of data signals that are serially received in series;
a two-unit interval (2UI) integrator which integrates the data signals that are serially received for a two-unit interval (2UI) of the data signals according to the plurality of clock signals and outputs an integrated signal;
a sampling circuit which obtains data by sampling the integrated signal integrated for an one-unit interval (1UI) and generates 2UI integrated data by sampling the integrated signal integrated for 2UI; and
an adaptive feedback circuit which analyzes a pattern of two or more data obtained in series and the 2UI integrated data and generates a phase control signal for adjusting a phase of the plurality of clock signals generated by the clock signal generation circuit.

2. The receiver according to claim 1,
wherein the adaptive feedback circuit,
when bit values of two consecutive data are different from each other, checks a pattern according to the bit values of the two consecutive data and the 2UI integrated data, and determines a phase difference between the plurality of data signals and the plurality of clock signals according to the checked pattern to generate the phase control signal.

3. The receiver according to claim 2,
wherein the adaptive feedback circuit
determines that the phase of the clock signals is ahead of the phase of the plurality of data signals, when the bit values of the two consecutive data are different from each other and a bit value of the 2UI integrated data is the same as a bit value of a first data of the two consecutive data, and
determines that the phase of the clock signals is behind the phase of the plurality of data signals, when the bit values of the two consecutive data are different from each other and the bit value of the 2UI integrated data is different from the bit value of the first data of the two consecutive data, to generate the phase control signal.

4. The receiver according to claim 1,
wherein the receiver further includes a DFE (Decision Feedback Equalization) that equalizes the integrated signal output from the 2UI integrator according to a DFE weight applied from the adaptive feedback circuit and transmits the equalized signal to the sampling circuit.

5. The receiver according to claim 4,
wherein the adaptive feedback circuit,
when bit values of two consecutive data are different from each other, check a pattern according to the bit values of the two consecutive data, previous data, and the 2UI integrated data, and determine an equalization state of the DFE according to the checked pattern to generate the DFE weight.

6. The receiver according to claim 5,
wherein the adaptive feedback circuit
determines that the equalization state of the DFE is an under-equalization state when the bit values of the two consecutive data are different from each other and the bit values of the previous data and the bit values of the 2UI integrated data are the same, and
determines that the equalization state of the DFE is an over-equalization state when the bit values of the two consecutive data are different from each other and the bit values of the previous data and the bit values of the 2UI integrated data are also different from each other, to generate the DFE weight.

7. The receiver according to claim 1,
wherein the clock signal generation circuit generates the plurality of clock signals having a 2UI cycle and a 90 degree phase difference from each other, and whose phases are adjusted according to the phase control signal.

8. The receiver according to claim 1,
wherein the 2UI integrator
receives two clock signals having a 2UI cycle and a 90 degree phase difference from each other, initialize a voltage level of a previously obtained integrated signal during a reset section in which both of the two clock signals are at a first level,
integrates the data signal during an integration section in which a first clock signal having a phase leading from among the two clock signals is at a second level, and generates the integrated signal, and
maintains the voltage level of the integrated signal during a hold section in which the first clock signal is at the first level and the level of a second clock signal is at the second level.

9. The receiver according to claim 8,
wherein the 2UI integrator includes
first and second detection circuits which are connected in parallel between a power supply voltage and a common node, and which apply the power supply voltage to an output node pair in the reset section in response to the two clock signals, connect the output node pair and the common node in accordance with the data signal in the integration section, and block the connection between the output node pair and the common node in accordance with the first clock signal in the hold section,
a bias circuit which is connected between the common node and a ground voltage and activates the first and second detection circuits by connecting the common node and the ground voltage in accordance with an applied bias voltage, and
an integration circuit which integrates a signal applied through the output node pair and outputs the integrated signal.

10. The receiver according to claim 9,
wherein each of the first and second detection circuits includes
two PMOS transistors connected in series between the power supply voltage and each of output nodes of the output node pair and receiving the first and second clock signals, respectively, and
two NMOS transistors connected in series between each of the output nodes of the output node pair and the common node and receiving one of the first clock signal and a data signal applied as a differential signal, respectively.

11. A method of operating a receiver, the method being performed in a receiver including a clock signal generation circuit, a 2Unit Interval (UI) integrator, a Decision Feedback Equalization (DFE), a sampling circuit, and an adaptive feedback circuit, the method comprising:
a step in which the clock signal generation circuit generates a plurality of clock signals from a received receiver clock signal together with a plurality of data signals that are serially received in series;
a step in which the 2UI integrator integrates the data signals that are serially received for a two-unit interval (2UI) of the data signals according to the plurality of clock signals and outputs an integrated signal;
a step in which the sampling circuit samples the integrated signal integrated for 1Unit Interval (UI) to obtain data and samples the integrated signal integrated for 2UI to generate 2UI integrated data; and
a step in which the adaptive feedback circuit analyzes a pattern of two or more data that are serially obtained and the 2UI integrated data to generate a phase control signal for adjusting a phase of the plurality of clock signals generated by the clock signal generation circuit.

12. The method of operating a receiver according to claim 11,
wherein the step of generating a phase control signal includes,
when bit values of two consecutive data are different from each other, checking a pattern according to the bit values of the two consecutive data and the 2UI integrated data, and determining a phase difference between the plurality of data signals and the plurality of clock signals according to the checked pattern, to generate the phase control signal.

13. The method of operating a receiver according to claim 12,
wherein the step of generating a phase control signal includes,
determining that the phase of the clock signals is ahead of the phase of the plurality of data signals, when the bit values of the two consecutive data are different from each other and a bit value of the 2UI integrated data is the same as a bit value of a first data of the two consecutive data, and
determining that the phase of the clock signals is behind the phase of the plurality of data signals, when the bit values of the two consecutive data are different from each other and the bit value of the 2UI integrated data is different from the bit value of the first data of the two consecutive data, to generate the phase control signal.

14. The method of operating a receiver according to claim 11,
wherein the method further includes
the step of equalizing the integrated signal output from the 2UI integrator according to a DFE weight applied from the adaptive feedback circuit and transmitting the equalized signal to the sampling circuit.

15. The method of operating a receiver according to claim 14,
wherein the step of generating a phase control signal includes,
when bit values of two consecutive data are different from each other, checking a pattern according to the bit values of the two consecutive data, previous data, and the 2UI integrated data, and determining an equalization state of the DFE according to the checked pattern to generate the DFE weight.

16. The method of operating a receiver according to claim 15,
wherein the step of generating a phase control signal includes,
determining that the equalization state of the DFE is an under-equalization state when the bit values of the two consecutive data are different from each other and the bit values of the previous data and the bit values of the 2UI integrated data are the same, and
determining that the equalization state of the DFE is an over-equalization state when the bit values of the two consecutive data are different from each other and the bit values of the previous data and the bit values of the 2UI integrated data are also different from each other, to generate the DFE weight.

17. The method of operating a receiver according to claim 15,
wherein the step of generating a phase control signal includes
alternately generating the phase control signal and the DFE weight while the plurality of data signals are received.

18. The method of operating a receiver according to claim 11,
wherein the step of generating the plurality of clock signals includes
generating the plurality of clock signals having a 2UI cycle and a 90 degree phase difference from each other, and whose phases are adjusted according to the phase control signal.

19. The method of operating a receiver according to claim 11,
wherein the step of outputting the integrated signal includes
receiving two clock signals having a 2UI cycle and a 90 degree phase difference from each other, initialize a voltage level of a previously obtained integrated signal during a reset section in which both of the two clock signals are at a first level,
integrating the data signal during an integration section in which a first clock signal having a phase leading from among the two clock signals is at a second level, and generate the integrated signal, and
maintaining the voltage level of the integrated signal during a hold section in which the first clock signal is at the first level and the level of a second clock signal is at the second level.
